(19) United States
(12) Patent Application Publication
(10) Pub. No.: US 2026/0130114 A1
(43) Pub. Date: May 7, 2026

(54) PIEZOELECTRIC DEVICE AND ULTRASONIC DEVICE

(71) Applicant: SEIKO EPSON CORPORATION, Tokyo (JP)

(72) Inventors: Chikara KOJIMA, MATSUMOTO-SHI (JP); Motoki TAKABE, SHIOJIRI-SHI (JP)

(21) Appl. No.: 19/378,877

(22) Filed: Nov. 4, 2025

(30) Foreign Application Priority Data
Nov. 6, 2024 (JP) 2024-194717

(51) Int. Cl. H10N 30/87; B06B 1/06; B60B 1/02

(52) U.S. Cl. CPC H10N 30/871; B06B 1/0655; B60B 1/0207

(57) ABSTRACT

A piezoelectric device includes: a substrate having a vibrating region and a non-vibrating region that surrounds the vibrating region; a first electrode provided across the vibrating region and the non-vibrating region; a second electrode disposed in the vibrating region to be separate from the first electrode; a piezoelectric body provided across the substrate, the first electrode, and the second electrode; and a third electrode that is disposed on the piezoelectric body and overlaps with at least the first electrode and the second electrode in the vibrating region when viewed in a thickness direction of the substrate.

The present application is based on, and claims priority from JP Application Serial Number 2024-194717, filed November 6, 2024, the disclosure of which is hereby incorporated by reference herein in its entirety.

### BACKGROUND

### 1. Technical Field

The present disclosure relates to a piezoelectric device and an ultrasonic device.

### 2. Related Art

There is a known piezoelectric device of related art in which a piezoelectric element is disposed at a vibrating plate and a voltage is applied to the piezoelectric element to vibrate the vibrating plate (refer, for example, to JP-A-2021-153293).

The piezoelectric device described in JP-A-2021-153293 is an ultrasonic device and includes a silicon substrate having a void, a vibrating plate that is provided on the silicon substrate and covers the void, a first electrode disposed on the vibrating plate, a piezoelectric body provided at a position where the piezoelectric body overlaps with the void when viewed in the thickness direction, and a second electrode provided on the piezoelectric body. In the ultrasonic device, the piezoelectric body is so disposed that 0.65 ≤ Pw/Cw ≤ 0.95 is satisfied, where Cw is the width of the void, and Pw is the width of the piezoelectric body.

JP-A-2021-153293 is an example of the related art.

A piezoelectric device of related art, such as that described in JP-A-2021-153293, however, has a problem of a small amount of deformation of the vibrating plate due to the fact that the piezoelectric body to which a voltage is applied bends the vibrating plate toward the void, but does not bend the vibrating plate toward the side opposite the void. Therefore, when the piezoelectric device is used as an ultrasonic device, the amount of deformation of the vibrating plate is small, so that the ultrasonic waves output from the ultrasonic device undesirably have a low sound pressure.

### SUMMARY

A piezoelectric device according to a first aspect of the present disclosure includes a substrate having a vibrating region and a non-vibrating region that surrounds the vibrating region; a first electrode provided across the vibrating region and the non-vibrating region; a second electrode disposed in the vibrating region to be separate from the first electrode; a piezoelectric body provided across the substrate, the first electrode, and the second electrode; and a third electrode that is disposed on the piezoelectric body and overlaps with at least the first electrode and the second electrode in the vibrating region when viewed in a thickness direction of the substrate.

An ultrasonic device according to a second aspect of the present disclosure includes the piezoelectric device according to the first aspect described above, and is configured to transmit ultrasonic waves by driving the piezoelectric device.

### BRIEF DESCRIPTION OF THE DRAWINGS

FIG. 1 is a cross-sectional view showing a schematic configuration of an ultrasonic device according to a first embodiment.

FIG. 2 is a plan view showing a schematic configuration of the ultrasonic device according to the first embodiment.

FIG. 3 shows displacement of a vibrating region that occurs when the ultrasonic device according to the first embodiment is driven.

FIG. 4 shows driving efficiency provided when (W1+W2)/Wc is changed in the first embodiment.

FIG. 5 shows the drive efficiency provided when W1/W2 is changed in the first embodiment.

FIG. 6 shows the drive efficiency provided when a phase difference Δφ between a first drive voltage and a second drive voltage is changed in the first embodiment.

FIG. 7 is a cross-sectional view showing a schematic configuration of an ultrasonic device according to a second embodiment.

FIG. 8 is a diagrammatic view showing a schematic configuration of a head according to a third embodiment.

FIG. 9 is a plan view showing a schematic configuration of a piezoelectric device according to Variation 2.

### DESCRIPTION OF EMBODIMENTS

### First embodiment

A first embodiment of the present disclosure will be described.

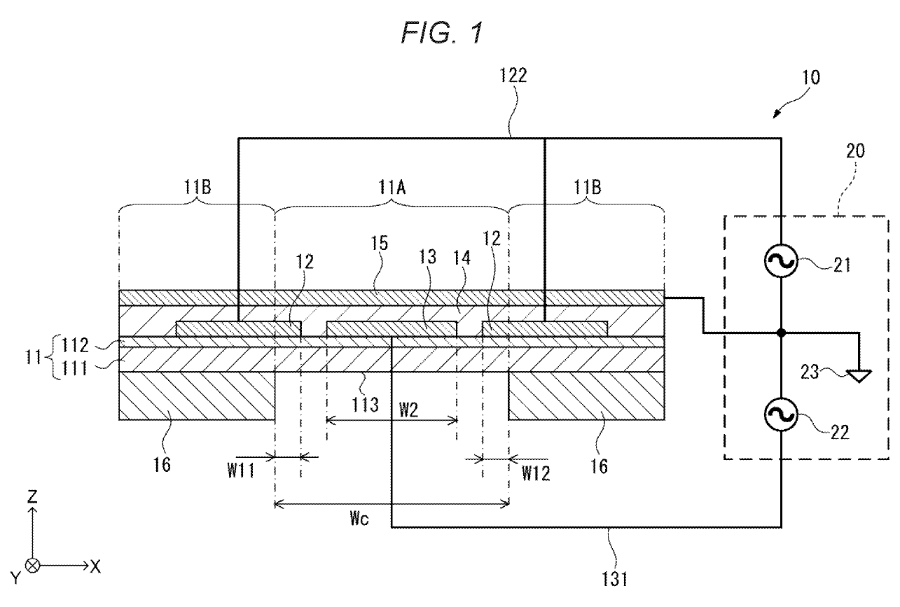

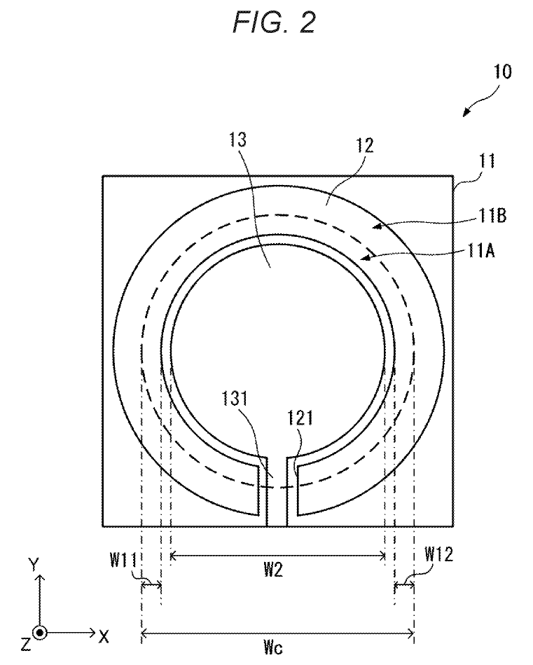

FIG. 1 is a cross-sectional view showing a schematic configuration of an ultrasonic device that is a piezoelectric device according to the present embodiment, and FIG. 2 is a plan view showing a schematic configuration of the ultrasonic device.

An ultrasonic device 10 includes a substrate 11, a first electrode 12, a second electrode 13, a piezoelectric body 14, a third electrode 15, a vibration suppressor 16, and a voltage controller 20, as shown in FIG. 1. Note that FIG. 2 does not show the piezoelectric body 14 and the third electrode 15.

In the present embodiment, the first electrode 12 and the second electrode 13 are layered on the substrate 11, the piezoelectric body 14 is layered to cover the substrate 11, the first electrode 12, and the second electrode 13, and the third electrode 15 is layered on the piezoelectric body 14. It is assumed in the following description that the thickness direction of the substrate 11, that is, the direction in which the substrate 11, the first electrode 12 (or second electrode 13), the piezoelectric body 14, and the third electrode 15 are layered on each other is a Z direction. It is further assumed that a plane perpendicular to the Z direction is an XY plane, and that two axial directions perpendicular to each other and contained in the XY plane are an X direction and a Y direction.

The substrate 11 includes a base 111 and a surface layer 112. The base 111 is a flat plate-shaped substrate configured with a semiconductor substrate, and is made of Si as the semiconductor substrate in the present embodiment. The surface layer 112 is a portion resulting from a surface treatment of the surface of the base 111. In the present embodiment, for example, one surface of the base 111 made of Si is oxidized to form SiO₂, and a ZrO₂ layer is further layered on the SiO₂ layer, for example, by sputtering. That is, in the present embodiment, the surface layer 112 includes the SiO₂ layer and the ZrO₂ layer.

Assuming that the −Z-side surface of the substrate 11 (surface at which surface layer 112 is not provided) is called a first surface 113, the first surface 113 is so formed that the arithmetic surface roughness thereof falls within a range of 0.4 ± 0.5 μm. That is, in the present embodiment, the first surface 113 of the substrate 11 is formed by polishing. The arithmetic surface roughness of the first surface 113 of the substrate 11 can thus be smaller than that achieved when the first surface 113 is formed, for example, by etching.

The substrate 11 has a vibrating region 11A and a non-vibrating region 11B, which surrounds the vibrating region 11A, as shown in FIGS. 1 and 2.

Note in FIG. 2 that the broken line indicates the boundary between the vibrating region 11A and the non-vibrating region 11B, and that the outside of the broken line is the non-vibrating region 11B and the inside of the broken line is the vibrating region 11A.

The vibrating region 11A is a region where the piezoelectric body 14 is deformed by application of a voltage to the space between the first electrode 12 and the third electrode 15 and a voltage to the space between the second electrode 13 and the third electrode 15, so that the vibrating region 11A vibrates, and the vibration of the vibrating region 11A causes the ultrasonic device 10 to output ultrasonic waves.

The non-vibrating region 11B is a region in which vibration is restricted. In the present embodiment, providing the vibration suppressor 16 at the first surface 113 of the non-vibrating region 11B of the substrate 11 suppresses vibration of the non-vibrating region 11B.

The vibration suppressor 16 is made of a resin providing a vibration suppressing effect. The resin to be used is not limited to a specific resin, and can, for example, be a resist resin such as an epoxy resin, an acrylic resin, or a novolak resin. The vibration suppressor 16 is provided to cover the entire non-vibrating region 11B and is not provided in the vibrating region 11A.

The first electrode 12 is provided in the Z direction on the surface layer 112 of the substrate 11 across the region from the vibrating region 11A to the non-vibrating region 11B.

In the present embodiment, the vibrating region 11A has a circular shape when viewed in the Z direction, and the first electrode 12 is formed along the circumferential direction of the circle of the vibrating region 11A, as shown in FIG. 2. A cutout 121 is provided at a portion of the first electrode 12. The cutout 121 is a portion where a second coupling wiring 131 coupled to the second electrode 13 is provided to extend across the region from the vibrating region 11A to the non-vibrating region 11B. Note that FIG. 2 shows a case where only one cutout 121 is provided, and multiple cutouts 121 may instead be provided at symmetrical positions with respect to the center of the vibrating region 11A in consideration of the stress balance during the vibration of the vibrating region 11A. For example, a pair of cutouts 121 that are point-symmetrical with respect to the center of the vibrating region 11A may be provided, or multiple cutouts 121 may be provided at positions (equiangular intervals) that are rotationally symmetrical with respect to the center of the vibrating region 11A.

In the present embodiment, the first electrode 12 is formed along the circumferential direction of the vibrating region 11A, as described above. This means that the first electrode 12 is disposed to sandwich the second electrode 13 in the cross-sectional view as shown in FIG. 1 (cross section excluding position where cutout 121 is provided).

A first coupling wiring 122 (see FIG. 1) is coupled to the first electrode 12, and the first coupling wiring 122 is electrically coupled to the voltage controller 20 via first terminals that are not shown but are provided at the surface layer 112 of the substrate 11.

The second electrode 13 is disposed in the vibrating region 11A of the substrate 11 to be separate from the first electrode 12. It is preferable that the second electrode 13 is formed in the same shape as the vibrating region 11A when viewed in the Z direction. In the present embodiment, since the vibrating region 11A has a circular shape, the second electrode 13 is also formed in a circular shape, so that the vibrating region 11A and the second electrode 13 are concentric circles, as shown in FIG. 2.

Furthermore, the second coupling wiring 131 is coupled to the second electrode 13, and the second coupling wiring 131 extends from the vibrating region 11A to the non-vibrating region 11B through the cutout 121 of the first electrode 12, as described above. The second coupling wiring 131 is electrically coupled to the voltage controller 20 via a second terminal that is not shown but is provided in the non-vibrating region 11B. Note that when the multiple cutouts 121 of the first electrode 12 are provided to be symmetrical with respect to the center point of the vibrating region 11A as described above, it is preferable that the second coupling wiring 131 is provided at each of the cutouts 121. The stress balance in the vibrating region 11A can thus be maintained.

In the XZ cross section (FIG. 1) passing through the center of the circular vibrating region 11A, let W11 and W12 be the widths of the first electrode 12 on the vibrating region 11A, W2 be the width of the second electrode 13, and Wc be the width of the vibrating region 11A.

In the present embodiment, the vibrating region 11A has a circular shape, and the width Wc of the vibrating region 11A is the diameter of the vibrating region 11A having a circular shape.

The first electrode 12 is formed to have a fixed width in the circumferential direction along the outer circumferential edge of the vibrating region 11A, and protrudes by a fixed width into the vibrating region 11A along the circumferential direction. The widths W11 and W12 of the first electrode 12 on the vibrating region 11A therefore satisfy W11 = W12. Furthermore, in the cross-sectional view shown in FIG. 1, let W1 be the sum of the widths of the pair of first electrode portions 12 disposed to sandwich the second electrode 13. That is, W1 = W11+W12, and in the present embodiment, W1 = 2W11.

The second electrode 13 has a circular shape concentric with the vibrating region 11A, and the width W2 of the second electrode 13 is the diameter of the second electrode 13.

In the ultrasonic device 10 according to the present embodiment, the sum W1 of the widths of the first electrode portions 12, the width W2 of the second electrode 13, and the width Wc of the vibrating region 11A satisfy the following relationship:

W1 < W2

0.25 ≤ W1/W2 ≤ 1

0.5 < (W1+W2)/Wc < 1

The piezoelectric body 14 is provided on the surface layer 112 of the substrate 11 across the region from the vibrating region 11A to the non-vibrating region 11B, and covers the first electrode 12 and the second electrode 13. That is, the piezoelectric body 14 entirely covers the vibrating region 11A, the first electrode 12, and the second electrode 13. The piezoelectric body 14 may be provided over the entire surface of the substrate 11. The piezoelectric body 14 is made, for example, of a perovskite transition metal oxide containing Pb, and is made of PZT containing Pb, Zr, and Ti in the present embodiment.

The third electrode 15 is provided on the piezoelectric body 14 across the region from the vibrating region 11A to the non-vibrating region 11B. That is, the third electrode 15 covers the first electrode 12 and the second electrode 13 in the vibrating region 11A when viewed in the Z direction.

A third coupling wiring 151 is coupled to the third electrode 15, and the third coupling wiring 151 is electrically coupled to the voltage controller 20 via a third terminal that is not shown but is provided in the non-vibrating region 11B.

The voltage controller 20 will next be described.

The voltage controller 20 is electrically coupled to the first electrode 12, the second electrode 13, and the third electrode 15, as described above.

The voltage controller 20 includes a first power supply 21, which applies a voltage to the first electrode 12, a second power supply 22, which applies a voltage to the second electrode 13, and a common potential portion 23 coupled to the third electrode 15. The first power supply 21 and the second power supply 22 each apply a drive voltage having a predetermined frequency.

The common potential portion 23 sets the third electrode 15, for example, to a predetermined common potential.

In the present embodiment, to drive the ultrasonic device 10, the voltage controller 20 provides a phase difference by shifting the phase of a first drive voltage applied from the first power supply 21 to the first electrode 12 from the phase of a second drive voltage applied from the second power supply 22 to the second electrode 13.

Specifically, a phase difference Δφ between the first drive voltage and the second drive voltage satisfies 150° ≤ Δφ ≤ 180°. Efficiency at which ultrasonic device 10 is driven

The efficiency at which the ultrasonic device 10 described above is driven will next be described.

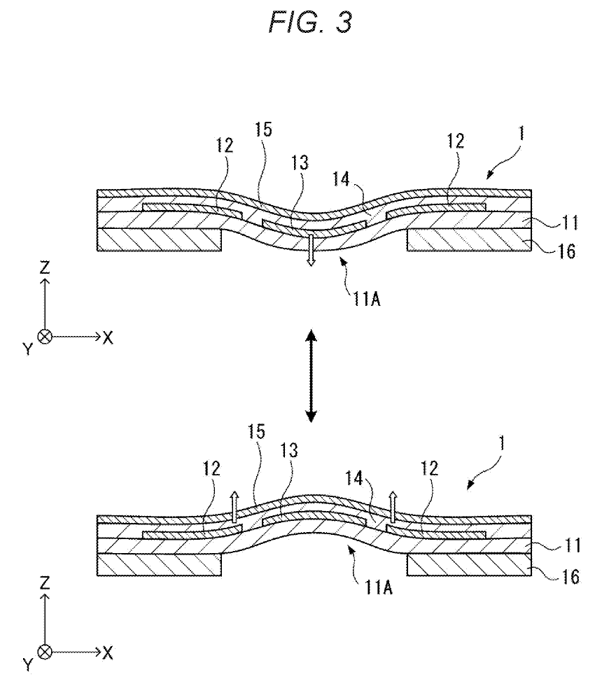

FIG. 3 shows displacement of the vibrating region 11A that occurs when the ultrasonic device 10 is driven.

In the present embodiment, when the second drive voltage is applied to the second electrode 13, the piezoelectric body 14 between the second electrode 13 and the third electrode 15 is deformed to protrude toward the −Z side, so that the vibrating region 11A is displaced to protrude toward the −Z side, as shown in the upper part of FIG. 3.

If only the second electrode 13 is provided but the first electrode 12 is not provided in the ultrasonic device 10, the vibrating region 11A is only displaced by the application of the drive voltage to the second electrode 13, that is, only displaced toward the −Z side. In this case, after the vibrating region 11A is displaced toward the −Z side, the vibrating region 11A is displaced toward the +Z side by the restoration force produced only by the springiness of the vibrating region 11A. A large displacement cannot be achieved only by the restoration force.

In contrast, in the present embodiment, the first drive voltage is applied to the space between the first electrode 12 and the third electrode 15 with the phase of the first drive voltage shifted from that of the second drive voltage applied to the second electrode 13. In this case, after the vibrating region 11A is displaced toward the −Z side by the application of the second drive voltage to the second electrode 13, the piezoelectric body 14 between the first electrode 12 and the third electrode 15 is deformed to warp toward the +Z side. The vibrating region 11A is therefore greatly displaced toward the +Z side by the deformation of the piezoelectric body 14 between the first electrode 12 and the third electrode 15 and the restoration force produced by the springiness of the vibrating region 11A, as shown in the lower part of FIG. 3.

In the present embodiment, alternate deformation of the vibrating region 11A from the state shown in the upper part to the state shown in the lower part in FIG. 3 and vice versa, the amplitude of the vibration of the vibrating region 11A can be increased as compared with a case where only the second electrode 13 and the third electrode 15 are provided, so that the sound pressure of the ultrasonic waves output from the ultrasonic device 10 also increases.

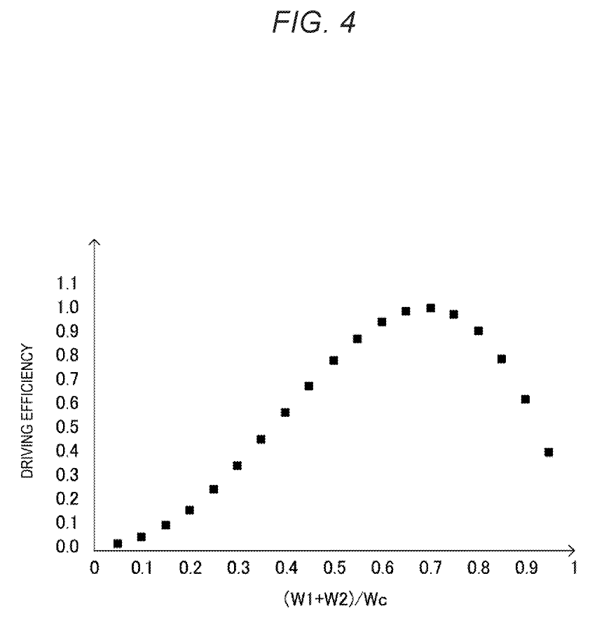

FIG. 4 shows the driving efficiency provided when (W1+W2)/Wc is changed. That is, the driving efficiency corresponds to the ratio of the sum W1 of the widths of the first electrode 12 added to the width W2 of the second electrode 13 to the width Wc of the vibrating region 11A.

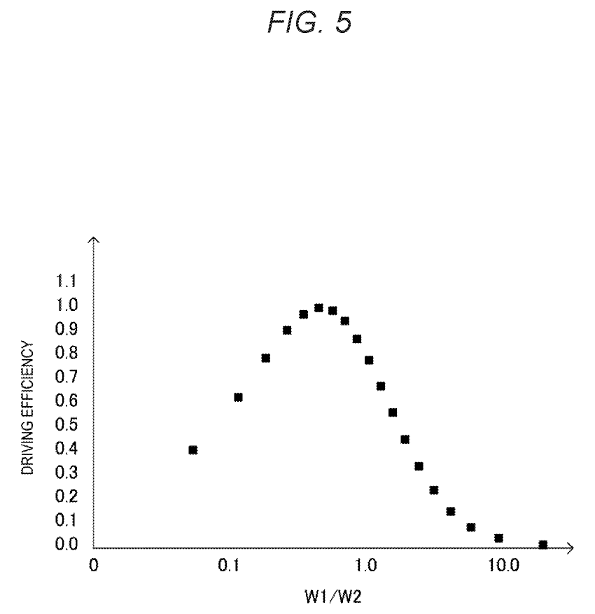

FIG. 5 shows the driving efficiency provided when W1/W2 is changed. That is, the driving efficiency corresponds to the sum W1 of the widths of the first electrode 12 to the width W2 of the second electrode 13.

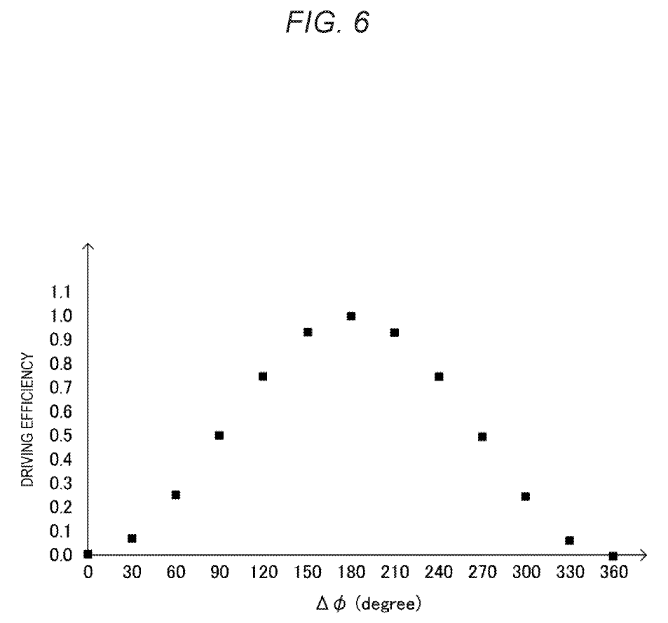

FIG. 6 shows the driving efficiency provided when the phase difference Δφ between the first drive voltage and the second drive voltage is changed.

Note that the driving efficiency indicates the magnitude of the amplitude of the vibration of the vibrating region 11A caused to vibrate on the assumption that the maximum amplitude is set to one.

Driving efficiency higher than or equal to 0.5 is achieved over a range where 0.5 < (W1+W2)/Wc < 1 is satisfied, as shown in FIG. 4. More preferably, when 0.6 < (W1+W2)/Wc < 0.8 is satisfied, driving efficiency higher than or equal to 0.9 is achieved.

Driving efficiency higher than or equal to 0.8 is achieved over a range where 0.25 ≤ W1/W2 ≤ 1 is satisfied, as shown in FIG. 5.

Driving efficiency higher than or equal to 0.9 is achieved over a range where 150° ≤ Δφ ≤ 210° is satisfied, as shown in FIG. 6.

In the present embodiment, the conditions of 0.25 ≤ W1/W2 ≤ 1 and 0.5 < (W1+W2)/Wc < 1 are satisfied, and the condition of 150° ≤ Δφ ≤ 210° is satisfied for the voltages applied by the voltage controller 20 to the first electrode 12 and the second electrode 13, as described above.

The amplitude of the vibration of the vibrating region 11A can therefore be further increased, so that the efficiency at which the ultrasonic device 10 is driven can be dramatically improved.

### Effects and advantages of present embodiment

The ultrasonic device 10 according to the present embodiment includes the substrate 11, the first electrode 12, the second electrode 13, the piezoelectric body 14, and the third electrode 15. The substrate 11 has the vibrating region 11A and the non-vibrating region 11B, which surrounds the vibrating region 11A. The first electrode 12 is provided at a +Z-side portion of the substrate 11 across the vibrating region 11A and the non-vibrating region 11B. The second electrode 13 is disposed inside the vibrating region 11A to be separate from the first electrode 12. The piezoelectric body 14 is provided across the substrate 11, the first electrode 12, and the second electrode 13. The third electrode 15 is provided on the piezoelectric body 14 and overlaps with the first electrode 12 and the second electrode 13 in the vibrating region 11A when viewed in the Z direction.

In the thus configured ultrasonic device 10, shifting the phase of the first drive voltage applied to the space between the first electrode 12 and the third electrode 15 from the phase of the second drive voltage applied to the space between the second electrode 13 and the third electrode 15 allows generation of stress that bends the vibrating region 11A toward both the positive and negative (±Z sides) in the Z direction, so that the amount of deformation (amplitude of vibration) of the vibrating region 11A can be increased. The sound pressure of the ultrasonic waves output from the ultrasonic device 10 can thus also be increased.

In the ultrasonic device 10 according to the present embodiment, the first electrode 12 is provided to sandwich the second electrode 13.

The vibrating region 11A thus has symmetrical stress balance, so that the amount of displacement during the vibration can be increased.

In the ultrasonic device 10 according to the present embodiment,

0.25 < W1/W2 ≤ 1, and

0.5 < (W1+W2)/Wc < 1

are satisfied,

where W1 is the sum of the widths of the portions of the first electrode 12 that are disposed in the vibrating region 11A, W2 is the width of the second electrode 13, and Wc is the width of the vibrating region 11A.

The amount of deformation of the vibrating region 11A can thus be increased, so that the efficiency at which the ultrasonic device 10 is driven can be maintained high.

The ultrasonic device 10 according to the present embodiment includes the voltage controller 20. The voltage controller 20 includes the first power supply 21, which applies the first drive voltage to the space between the first electrode 12 and the third electrode 15, and the second power supply 22, which applies the second drive voltage to the space between the second electrode 13 and the third electrode 15. The voltage controller 20 then inputs the first and second drive voltages to the ultrasonic device 10 with the phases of the two voltages being different from each other.

Applying the second drive voltage to the space between the second electrode 13 and the third electrode 15 causes deformation of the piezoelectric body 14 to bend the vibrating region 11A toward the −Z side, and applying the first drive voltage to the space between the first electrode 12 and the third electrode 15 causes deformation of the piezoelectric body 14 to bend the vibrating region 11A toward the +Z side. Shifting the phase of the first drive voltage from the phase of the second drive voltage causes the timing at which the stress that bends the vibrating region 11A toward the +Z side is induced to be shifted from the timing at which the stress that bends the vibrating region 11A toward the −Z side is induced, so that the amount of displacement of the vibrating region 11A can be increased.

In this process, the difference Δφ in phase between the first drive voltage and the second drive voltage satisfies 150° ≤ Δφ ≤ 210°.

Therefore, after the stress that bends the vibrating region 11A toward the −Z side is induced by the second drive voltage, and when the vibrating region 11A returns toward the +Z side due to the spring force produced by the substrate 11, the stress that bends the vibrating region 11A toward the +Z side can be induced by the first drive voltage. Similarly, after the stress that bends the vibrating region 11A toward the +Z side is induced by the first drive voltage, and when the vibrating region 11A returns toward the −Z side due to the spring force produced by the substrate 11, the stress that bends the vibrating region 11A toward the −Z side can be induced by the second drive voltage. That is, in the present embodiment, the amount of deformation of the vibrating region 11A can be further increased by the resultant force of the spring force produced by the substrate 11 and the stress induced by the deformation of the piezoelectric body 14.

### Second embodiment

In the first embodiment described above, the vibration suppressor 16 is provided at the first surface 113, which is the −Z-side surface of the substrate 11, and the vibration suppressor may instead be provided on the +Z side of the substrate 11.

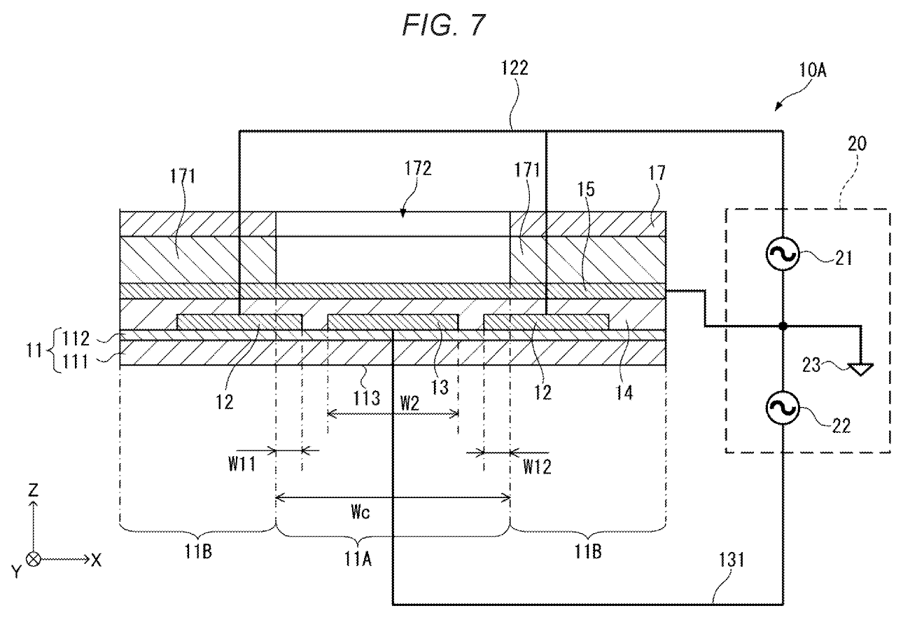

FIG. 7 shows a schematic configuration of an ultrasonic device 10A according to a second embodiment. In the following description, the elements having been already described have the same reference characters, and will not be described.

The ultrasonic device 10A according to the second embodiment includes the substrate 11, the first electrode 12, the second electrode 13, the piezoelectric body 14, the third electrode 15, a support substrate 17, and the voltage controller 20, as shown in FIG. 7.

The ultrasonic device 10A according to the present embodiment is provided with the support substrate 17, which is disposed on the +Z side of the substrate 11 and faces the third electrode 15. The support substrate 17 is provided, for example, to reinforce the substrate 11 having a small thickness, and is bonded to at least one of the substrate 11, the piezoelectric body 14, and the third electrode 15 via a support leg 171. The support leg 171 can, for example, be made of a resist resin such as an epoxy resin, an acrylic resin, or a novolak resin, and suppresses the vibration of the non-vibrating region 11B, as the vibration suppressor 16 in the first embodiment. In the example shown in FIG. 7, the support leg 171 is bonded to the entire non-vibrating region 11B. The support leg 171 therefore functions in the same manner as the vibration suppressor 16 in the first embodiment.

The support substrate 17 may be provided with a through hole 172, which passes through the support substrate 17 in the Z direction, at a position where the through hole 172 overlaps with the vibrating region 11A when viewed in the Z direction.

Providing the thus configured through hole 172 allows the ultrasonic waves generated by the vibrating region 11A to be output toward both the ±Z sides.

In the example shown in FIG. 7, the piezoelectric body 14 and the third electrode 15 cover the entire non-vibrating region 11B. Instead, the third electrode 15 may cover only a portion of the non-vibrating region 11B, and the end edge of the third electrode 15 may be located on the piezoelectric body 14. In this case, the end edge of the third electrode 15 and the piezoelectric body 14 are covered with the support leg 171, so that occurrence of cracks or burnout at the boundary between the end edge of the third electrode 15 and the piezoelectric body 14 can be suppressed.

Instead, both the piezoelectric body 14 and the third electrode 15 may be configured to cover only a portion of the non-vibrating region 11B. In this case, the support leg 171 is bonded to the end edge of the third electrode 15, the end edge of the piezoelectric body 14, and a portion of the surface layer 112 of the substrate 11 that is the portion at which neither the piezoelectric body 14 nor the third electrode 15 is provided.

The ultrasonic device 10A according to the second embodiment described above can also provide the same effects and advantages as those provided by the ultrasonic device 10 according to the first embodiment.

In addition to the above, in the ultrasonic device 10A according to the present embodiment, the support substrate 17 disposed to face the third electrode 15 is provided on the +Z side of the substrate 11, and the support substrate 17 is bonded to at least one of the substrate 11, the piezoelectric body 14, and the third electrode 15 via the support leg 171 in the non-vibrating region 11B. That is, in the present embodiment, since the support leg 171 is bonded to the non-vibrating region 11B, the vibration of the non-vibrating region 11B is suppressed, and the vibrating region 11A is allowed to vibrate.

In the configuration described above, the substrate 11 can be reinforced by the support substrate 17, so that damage to the substrate 11 can be suppressed. In addition, the support leg 171 bonded to the non-vibrating region 11B eliminates the need to provide the vibration suppressor 16 on the −Z side of the substrate 11.

In the ultrasonic device 10A according to the present embodiment, the support substrate 17 may be provided with the through hole 172 in a portion where the through hole 172 overlaps with the vibrating region 11A when viewed in the Z direction.

The ultrasonic waves generated by the vibration of the vibrating region 11A can therefore be output toward both the ±Z sides of the substrate 11.

### Third embodiment

In the first embodiment described above, the ultrasonic device 10 that outputs ultrasonic waves is presented as an example of the piezoelectric device, but not necessarily.

For example, the piezoelectric device according to an aspect of the present disclosure can be used as a piezoelectric device that applies pressure to a target object, and may be used, for example, as a piezoelectric device provided in a head of an inkjet printer.

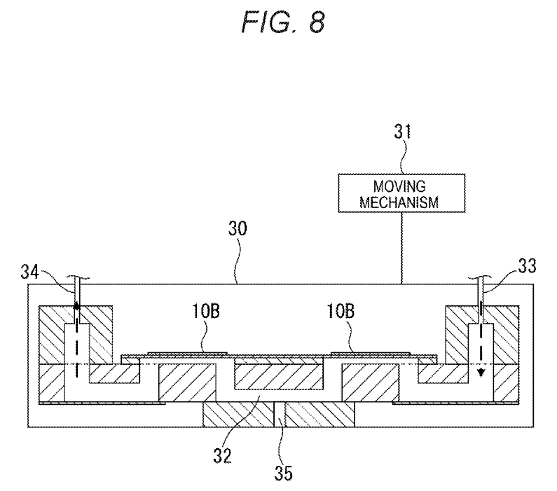

FIG. 8 shows a schematic configuration of a head including a piezoelectric device 10B.

In FIG. 8, a head 30 is an apparatus that is provided in an inkjet printer (not shown) and discharges ink onto a print medium.

The head 30 is provided to be movable along a predetermined scan direction with the aid of a moving mechanism 31 provided in the inkjet printer.

The head 30 includes an ink chamber 32, which stores ink, and a supply tube 33, through which the ink is supplied, a circulation tube 34, through which the ink is circulated, and other tubes are coupled to the ink chamber 32. The ink chamber 32 is provided with a nozzle 35, which faces the print medium, and the piezoelectric device 10B, which applies pressure to the ink in the ink chamber 32.

After the thus configured head 30 is moved to a predetermined position on the print medium under the control of a controller that is not shown, the piezoelectric device 10B is driven under the control of the controller, so that the ink is discharged from the ink chamber 32 onto the print medium via the nozzle 35.

In this process, the piezoelectric device 10B can increase the amplitude of the vibration of the vibrating region 11A, and can appropriately discharge the ink via the nozzle, as described above.

### Variations

Note that the present disclosure is not limited to the embodiments described above, and the present disclosure includes configurations derived from variations and improvements of the embodiments within a scope in which an object of the present disclosure can be achieved, appropriate combinations of the embodiments, and the like.

### Variation 1

For example, the first embodiment may also have the configuration in which the support substrate 17 and the support leg 171 are provided on the +Z side of the substrate 11, as the second embodiment having the configuration in which the support substrate 17 and the support leg 171 are provided.

In this case, the vibration suppressor 16 and the support leg 171 are provided on the ±Z sides of the substrate 11 in the non-vibrating region 11B, respectively.

The second embodiment has the configuration in which the support substrate 17 is provided by way of example, and may instead have a configuration in which the support substrate 17 is not provided but only the support leg 171 is provided.

### Variation 2

In the first embodiment described above, the case where the vibrating region 11A has a circular shape has been presented, and the vibrating region 11A may be formed in another shape having the minor axis direction and the major axis direction.

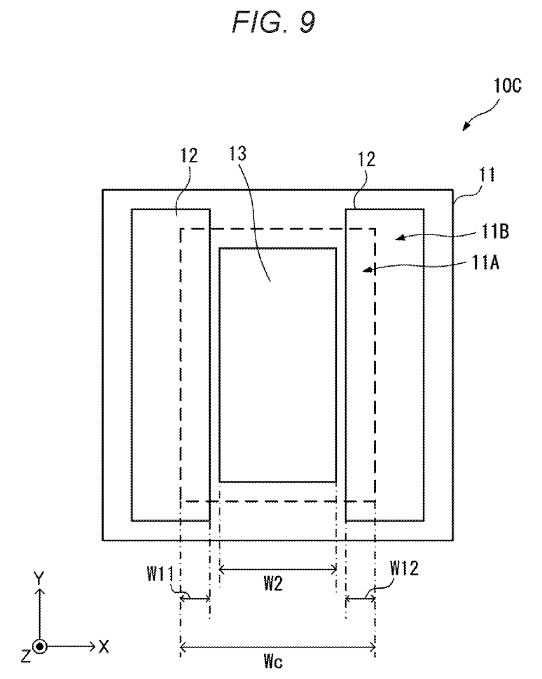

FIG. 9 is a plan view of a piezoelectric device 10C in a case where the vibrating region 11A has a rectangular shape. FIG. 9 does not show the piezoelectric body 14 or the third electrode 15.

For example, in the piezoelectric device 10C shown in FIG. 9, the vibrating region 11A is formed in a rectangular shape having a minor axis direction that coincides with the X direction and a major axis direction that coincides with the Y direction.

In this case, the first electrode 12 is provided across each region from the vibrating region 11A and the non-vibrating region 11B along sides parallel to the major axis direction, that is, a pair of major sides.

The second electrode 13 is provided in the vibrating region 11A as in the embodiments described above. Since the first electrodes 12 are provided along the pair of major sides of the vibrating region 11A, the second electrode 13 having a rectangular shape elongated in the major axis direction is provided to be sandwiched between the first electrodes 12.

The piezoelectric body 14 and the third electrode 15 are the same as those in the embodiments described above, and are disposed to cover the first electrodes 12 and the second electrode 13 across the region from the vibrating region 11A to the non-vibrating region 11B. Furthermore, the vibration suppressor 16 is disposed in the non-vibrating region 11B of the first surface 113 of the substrate 11, as in the first embodiment. Instead, the support substrate 17 facing the third electrode 15 may be disposed, and the support leg 171 may be bonded to the support substrate 17 at the portion corresponding to the non-vibrating region 11B, as in the second embodiment.

The cross section of the piezoelectric device 10C taken along the XZ plane is therefore the same as that in the first embodiment shown in FIG. 1 or the second embodiment shown in FIG. 7.

In this case, the vibrating region 11A, the first electrodes 12, and the second electrode 13 are so configured that

W1<W2,

0.25 ≤ W1/W2 ≤ 1, and

0.5 < (W1+W2)/Wc < 1

are satisfied, where W1 is the sum of widths W11 and W12 of portions of the first electrodes 12 in the vibrating region 11A that are the portions along the minor axis direction, and W2 is the width of the second electrode 13 along the minor axis direction.

The amplitude of the vibration of the vibrating region 11A can therefore be increased, so that the driving efficiency can be increased, as in the embodiments described above.

Note that FIG. 9 shows the case where the pair of first electrodes 12 are provided along the major sides of the vibrating region 11A, and that the first electrodes 12 may be disposed to surround the outer circumference of the vibrating region 11A as in the embodiments described above.

### Variation 3

The embodiments described above and Variation 2 shown in FIG. 9 show the case where the first electrode 12 is disposed to sandwich the second electrode 13, but not necessarily. For example, in the embodiments described above, the first electrode 12 may be provided only on the +X side (or only on −X side) of the second electrode 13. When the vibrating region 11A has a rectangular shape as shown in FIG. 9, the first electrode 12 may be provided only along one major side of the vibrating region 11A. In this case, the vibrating region 11A, the first electrode 12, and the second electrode 13 are so configured that

W1 < W2,

0.25 ≤ W1/W2 ≤ 1, and

0.5 < (W1+W2)/Wc < 1

are satisfied, where W1 is the width of the first electrode 12 in the vibrating region 11A.

### Summary of present disclosure

A piezoelectric device according to a first aspect of the present disclosure includes a substrate having a vibrating region and a non-vibrating region that surrounds the vibrating region; a first electrode provided across the vibrating region and the non-vibrating region; a second electrode disposed in the vibrating region to be separate from the first electrode; a piezoelectric body provided across the substrate, the first electrode, and the second electrode; and a third electrode that is disposed on the piezoelectric body and overlaps with at least the first electrode and the second electrode in the vibrating region when viewed in a thickness direction of the substrate.

In the thus configured piezoelectric device, shifting the phase of a drive voltage applied to the space between the first electrode and the third electrode from the phase of a drive voltage applied to the space between the second electrode and the third electrode allows alternate generation of stress that bends the vibrating region toward the piezoelectric body and stress that bends the vibrating region toward the side opposite the piezoelectric body, so that the amount of deformation (amplitude of vibration) of the vibrating region can be increased.

In the piezoelectric device according to the present aspect, when viewed in the thickness direction, it is preferable that a width of a portion of the first electrode that is a portion disposed in the vibrating region is smaller than or equal to a width of the second electrode, and that a sum of the width of the first electrode disposed in the vibrating region and the width of the second electrode is smaller than a width of the vibrating region.

The amount of deformation of the piezoelectric device can thus be further increased as compared with a case where the width of a portion of the first electrode that is the portion disposed in the vibrating region is greater than the width of the second electrode.

In the piezoelectric device according to the present aspect, it is preferable that the first electrode is provided to sandwich the second electrode.

The vibrating region thus has symmetrical stress balance, so that the amount of displacement during the vibration can be increased.

In the piezoelectric device according to the present aspect, it is preferable that 0.25 < W1/W2 ≤ 1 and 0.5 < (W1+W2)/Wc < 1 are satisfied, where W1 is a sum of widths of portions of the first electrode that are disposed in the vibrating region, W2 is the width of the second electrode, and Wc is the width of the vibrating region.

Therefore, when 0.25 > W1/W2 is satisfied, the amount of deformation of the piezoelectric device can be increased as compared with a case where 0.5 > (W1+W2)/Wc is satisfied.

In the piezoelectric device according to the present aspect, it is preferable that the piezoelectric device further includes a voltage applicator configured to apply a voltage to a space between the first electrode and the third electrode and a voltage to a space between the second electrode and the third electrode, and that the voltage applicator is configured to make a phase of the voltage applied to the space between the first electrode and the third electrode different from a phase of the voltage applied to the space between the second electrode and the third electrode.

In the piezoelectric device according to the present aspect, applying a voltage to the space from the second electrode and the piezoelectric body to the third electrode causes stress to act so as to displace the vibrating region toward the side opposite the piezoelectric body, and applying a voltage to the space from the first electrode and the piezoelectric body to the third electrode causes stress to act so as to displace the vibrating region toward the piezoelectric body. Therefore, making the phase of the voltage applied to the space between the first electrode and the third electrode different from the phase of the voltage applied to the space between the second electrode and the third electrode allows stress to be induced in each of the displacement directions of the vibrating region, so that the amount of displacement of the vibrating region can be increased.

In this case, it is preferable that 150° ≤ Δφ ≤ 210° is satisfied, where Δφ is a difference in phase between the voltage applied to the space between the first electrode and the third electrode and the voltage applied to the space between the second electrode and the third electrode.

Therefore, applying a voltage to the space from the second electrode and the piezoelectric body to the third electrode, the vibrating region is displaced toward the side opposite the piezoelectric body, and when the vibrating region returns toward the piezoelectric body due to the spring force produced by the substrate, applying a voltage to the space from the first electrode and the piezoelectric body to the third electrode allows deformation of the piezoelectric body to induce stress that displaces the vibrating region toward the piezoelectric body. The amount of deformation of the vibrating region can therefore be further increased by the resultant force of the spring force produced by the substrate and the stress induced by the deformation of the piezoelectric body.

The piezoelectric device according to the present aspect may include: a support substrate disposed to face a side of the third electrode that is a side opposite the substrate; and a support leg configured to bond at least one of the substrate, the piezoelectric body, and the third electrode to the support substrate in the non-vibrating region.

In the configuration described above, the substrate can be reinforced by the support substrate, so that damage to the substrate can be suppressed. In addition, bonding the support leg to the non-vibrating region allows the support leg to function as a vibration suppressing member that suppresses vibration of the non-vibrating region.

In this case, the support substrate may have a through hole in a portion where the through hole overlaps with the vibrating region when viewed in the thickness direction.

Ultrasonic waves generated by the vibration of the vibrating region can therefore be output to both a side of the substrate that is the side facing the piezoelectric body and a side of the substrate that is the side opposite the piezoelectric body.

An ultrasonic device according to a second aspect of the present disclosure includes the piezoelectric device described above, and is configured to transmit ultrasonic waves by driving the piezoelectric device.

Ultrasonic waves having high sound pressure can thus be output.

What is claimed is:

1. A piezoelectric device comprising:
a substrate having a vibrating region and a non-vibrating region that surrounds the vibrating region;
a first electrode provided across the vibrating region and the non-vibrating region;
a second electrode disposed in the vibrating region to be separate from the first electrode;
a piezoelectric body provided across the substrate, the first electrode, and the second electrode; and
a third electrode that is disposed on the piezoelectric body and overlaps with at least the first electrode and the second electrode in the vibrating region when viewed in a thickness direction of the substrate.

2. The piezoelectric device according to claim 1, wherein
a width of a portion of the first electrode that is a portion disposed in the vibrating region is smaller than or equal to a width of the second electrode, and a sum of the width of the first electrode disposed in the vibrating region and the width of the second electrode is smaller than a width of the vibrating region.

3. The piezoelectric device according to claim 2, wherein
the first electrode is provided to sandwich the second electrode in a direction intersects with the thickness direction.

4. The piezoelectric device according to claim 3, wherein
0.25 < W1/W2 ≤ 1, and
0.5 < (W1+W2)/Wc < 1
are satisfied, where W1 is a sum of widths of portions of the first electrode that are disposed in the vibrating region, W2 is the width of the second electrode, and Wc is the width of the vibrating region.

5. The piezoelectric device according to claim 1, comprising
a voltage applicator configured to apply a voltage to a space between the first electrode and the third electrode and a voltage to a space between the second electrode and the third electrode,
wherein the voltage applicator is configured to make a phase of the voltage applied to the space between the first electrode and the third electrode different from a phase of the voltage applied to the space between the second electrode and the third electrode.

6. The piezoelectric device according to claim 5, wherein
150° ≤ Δφ ≤ 210°
is satisfied, where Δφ is a difference in phase between the voltage applied to the space between the first electrode and the third electrode and the voltage applied to the space between the second electrode and the third electrode.

7. The piezoelectric device according to claim 1, comprising:
a support substrate disposed to face a side of the third electrode that is a side opposite the substrate; and
a support leg configured to bond at least one of the substrate, the piezoelectric body, and the third electrode to the support substrate in the non-vibrating region.

8. The piezoelectric device according to claim 7, wherein
the support substrate has a through hole in a portion where the through hole overlaps with the vibrating region in the thickness direction.

9. An ultrasonic device comprising:
the piezoelectric device according to claim 1,
wherein the ultrasonic device is configured to transmit ultrasonic waves by driving the piezoelectric device.
